(19) United States
(12) Patent Application Publication
(10) Pub. No.: US 2025/0071946 A1
(43) Pub. Date: Feb. 27, 2025

(54) THERMAL CONDUCTIVE STRUCTURE AND PHOTOELECTRIC CONVERSION MODULE

(71) Applicant: Lumentum Operations LLC, San Jose, CA (US)

(72) Inventor: Chieh-Tse HUANG, Taoyuan City (TW)

(21) Appl. No.: 18/798,127

(22) Filed: Aug. 8, 2024

(30) Foreign Application Priority Data
Aug. 21, 2023 (TW) 112131323

(51) Int. Cl. H05K 7/20

(52) U.S. Cl. CPC H05K 7/2039

(57) ABSTRACT

A heat conduction structure comprising: a heat absorption wall, a heat conduction wall, and two side walls, wherein an accommodation space is formed and surrounded by the heat absorption wall, the heat conduction wall, and the two side walls, wherein the heat absorption wall, the heat conduction wall, and the two side walls are formed by bending a monolithic material, the heat absorption wall is formed by two ends of the monolithic material, and a gap is existed between the two ends of the monolithic material on a plane where the heat absorption wall is located. The present invention further provides a photoelectric conversion module comprising a photoelectric conversion circuit board and the aforementioned heat conduction structure, the photoelectric conversion circuit board being arranged in the accommodation space, and at least two of a plurality of heat generating elements of the photoelectric conversion circuit board being located on two sides of the gap, respectively. The heat conduction structure and the photoelectric conversion module of the present invention solve the problem of low heat conduction efficiency for electronic elements in the prior art, and can minimize the thermal interference effect resulted from a plurality of heat sources.

### CROSS-REFERENCE TO RELATED APPLICATION

This Patent application claims priority to Taiwan Patent Application No. 112131323, filed on Aug. 21, 2023, and entitled “THERMAL CONDUCTIVE STRUCTURE AND PHOTOELECTRIC CONVERSION MODULE.” The disclosure of the prior Application is considered part of and is incorporated by reference into this Patent Application.

### TECHNICAL FIELD

The present invention relates to a heat conduction structure and a photoelectric conversion module, and more particularly, to a heat conduction structure and a photoelectric conversion module with high heat dissipation efficiency.

### BACKGROUND

Optical transmission components such as an optical fiber or a planar waveguide have lower energy loss rates compared with a cable for transmitting electrical signals. Therefore, during transmission of signals, a laser emitting component is usually used to convert an electrical signal into an optical signal and send the optical signal to a transmission end of an optical transmission component; the optical signal is transmitted to an output end through the optical transmission component, and is transmitted from the optical transmission component toward an optical signal receiving component; and the optical signal receiving component converts the optical signal into the electrical signal. A module that provides mutual conversion between an optical signal and an electrical signal is referred to as a photoelectric conversion module. The photoelectric conversion module typically includes electronic elements such as a circuit board, a photodiode, and a laser.

In a conversion process, heat generating elements such as the photodiode and the laser have extremely high working temperatures, so that they may work stably only if the heat energy is dissipated quickly. The common practice is to stack elements such as a heat conduction bump and a heat conduction plate on the heat generating elements layer by layer, and fill gaps with heat conduction glue to transfer the heat energy from the heat generating elements located on a circuit board to fins on a surface of the photoelectric conversion module. In other words, a conduction path of the heat energy needs to pass through a plurality of different heat conduction elements, and thus the heat conduction efficiency is poor. The heat conductivity of the heat conduction glue is lower than that of ordinary metals. If the plurality of heat generating elements generate heat simultaneously in adjacent areas, a traditional heat dissipation structure is unable to quickly and effectively dissipate the heat energy. As a result, the heat energy is accumulated in the module.

### SUMMARY

Therefore, in order to solve various problems of the conventional heat conduction structure and photoelectric conversion module, the present invention relates to a heat conduction structure and a photoelectric conversion module with high heat dissipation efficiency.

To achieve the above objectives and other objectives, the present invention provides a heat conduction structure, comprising: a heat absorption wall; a heat conduction wall; and two side walls connected to the heat absorption wall and the heat conduction wall, an accommodation space being formed and surrounded by the heat absorption wall, the heat conduction wall, and the two side walls, wherein the heat absorption wall, the heat conduction wall, and the two side walls are formed by bending a monolithic material, the heat absorption wall is formed by two ends of the monolithic material, and a gap is existed between the two ends of the monolithic material on a plane where the heat absorption wall is located.

In an embodiment of the present invention, the heat absorption wall has a contact protrusion toward the accommodation space, and the contact protrusion is formed by stamping the monolithic material.

In an embodiment of the present invention, the heat conduction structure further includes an extension portion parallel to the heat conduction wall, and the extension portion is formed by bending the monolithic material.

The present invention further provides a photoelectric conversion module, comprising: a heat conduction structure having a heat absorption wall, a heat conduction wall, and two side walls connected to the heat absorption wall and the heat conduction wall, an accommodation space being formed and surrounded by the heat absorption wall, the heat conduction wall, and the two side walls; and a photoelectric conversion circuit board arranged in the accommodation space, the photoelectric conversion circuit board being provided with a plurality of heat generating elements, wherein the heat absorption wall, the heat conduction wall, and the two side walls are formed by bending a monolithic material, the heat absorption wall is formed by two ends of the monolithic material, and a gap is existed between the two ends of the monolithic material on a plane where the heat absorption wall is located, at least two of the plurality of heat generating elements are located on two sides of the gap, respectively.

In an embodiment of the present invention, the heat conduction structure is provided with a first limiting feature at a first end in an assembling direction, and the first limiting feature is a groove parallel to the assembling direction.

In an embodiment of the present invention, the heat conduction structure is provided with a second limiting feature at a second end in an assembling direction, the second limiting feature is protruded from the side wall toward the accommodation space, the second limiting feature has a snap-fit recessed hole, and the photoelectric conversion circuit board is provided with a snap-fit bump at a position corresponding to the snap-fit recessed hole.

In an embodiment of the present invention, the second limiting feature has a guide slope in the assembling direction, and the guide slope is inclined with respect to the assembling direction.

In an embodiment of the present invention, the photoelectric conversion module further includes a housing, and the heat conduction structure is configured to be slidably arranged in the housing.

In an embodiment of the present invention, the housing has a third limiting feature; and the third limiting feature protrudes toward the heat conduction structure in two directions perpendicular to an assembling direction to restrict movement of the heat conduction structure beyond the assembling direction.

In an embodiment of the present invention, the heat conduction structure further includes at least one elastic sheet arranged on the heat absorption wall, the elastic sheet is provided with a positioning protrusion toward the housing, a bottom surface of the housing has at least one positioning recess at a position corresponding to the positioning protrusion.

Thereby, the photoelectric conversion module of the present invention uses, by means of a heat conduction structure formed by a monolithic material, a monolithic structure that is not connected with other heterogeneous material, to directly transfer heat energy from the bottom of the photoelectric conversion circuit board through the sides to the top, without the need of heat conduction through numerous different stacked and complex heat conduction elements. In addition, when a plurality of heat generating elements generate heat simultaneously in adjacent areas, the heat conduction structure of the present invention is to be provided with two ends of the monolithic material far away from each other being in thermal contact with the heat generating elements respectively, so that the heat sources are not accumulated in a specific area of the monolithic material, and the heat may be quickly dissipated away from two sides, thereby avoiding overheating of the photoelectric conversion circuit board and maintaining good operation thereof.

### BRIEF DESCRIPTION OF THE DRAWINGS

FIG. 1A is a perspective diagram of a heat conduction structure according to an embodiment of the present invention.

FIG. 1B is a front-view diagram of a heat conduction structure according to an embodiment of the present invention.

FIG. 2A is a perspective cross-sectional diagram of a photoelectric conversion module according to an embodiment of the present invention.

FIG. 2B is a front-view diagram of a cross section of a photoelectric conversion module according to an embodiment of the present invention.

FIG. 3A is a bottom-view diagram of a heat conduction structure according to an embodiment of the present invention.

FIG. 3B is a bottom-view diagram of a heat conduction structure in another form according to an embodiment of the present invention.

FIG. 4A is a schematic diagram I of an assembling of a photoelectric conversion module according to an embodiment of the present invention.

FIG. 4B is a schematic diagram of an assembling of a second limiting feature according to an embodiment of the present invention.

FIG. 5A is a schematic diagram II of an assembling of a photoelectric conversion module according to an embodiment of the present invention.

FIG. 5B is a perspective diagram of a photoelectric conversion module in another viewing angle according to an embodiment of the present invention.

### DETAILED DESCRIPTION

To fully understand the present invention, the following specific embodiments and accompanying drawings are used to provide a detailed explanation to the present invention. A person skilled in the art can understand the objectives, features, and effects of the present invention from the contents disclosed in this specification. It should be noted that the present invention can also be implemented or applied through other different specific embodiments, and various details in this specification can be modified and changed in various ways based on different perspectives and applications without departing from the spirit of the present invention. The following implementations will further explain the relevant technical content of the present invention in detail, but the disclosed content is not intended to limit the scope of the patent application of the present invention. Explanations are as follow.

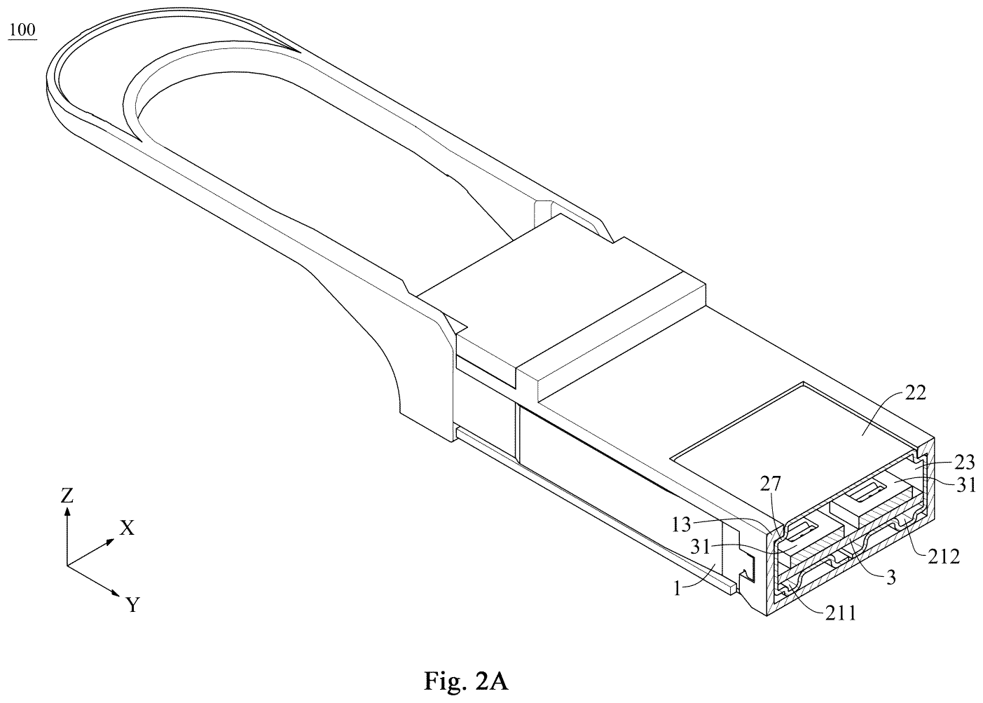

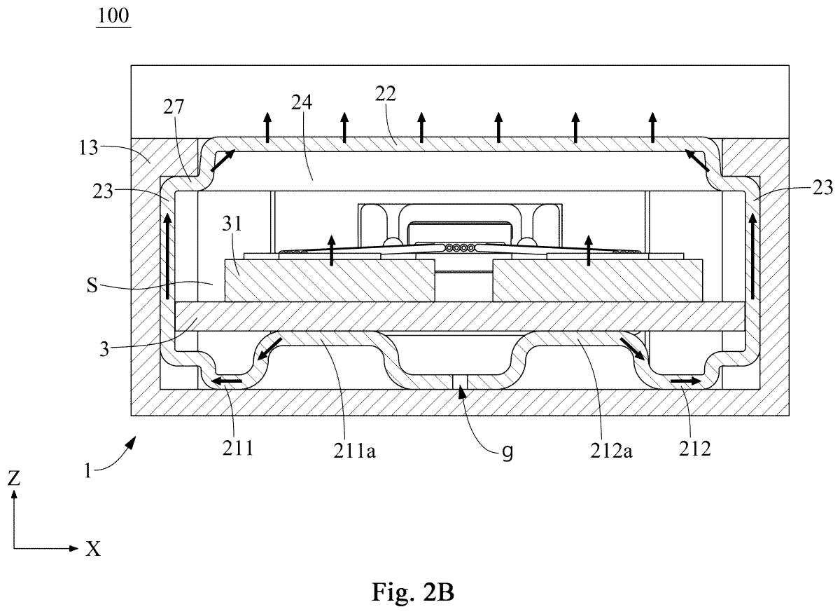

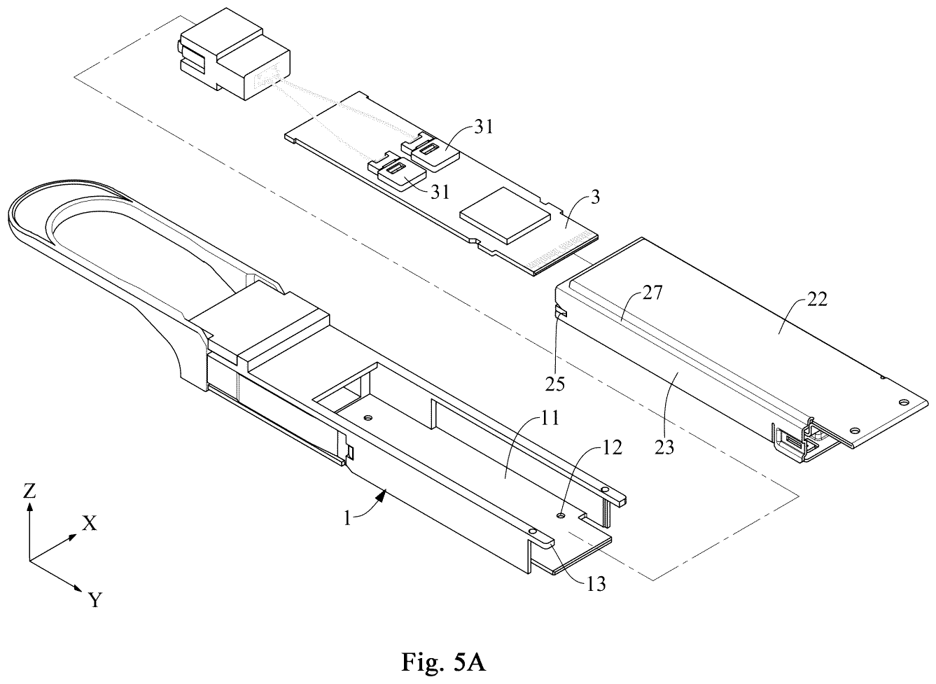

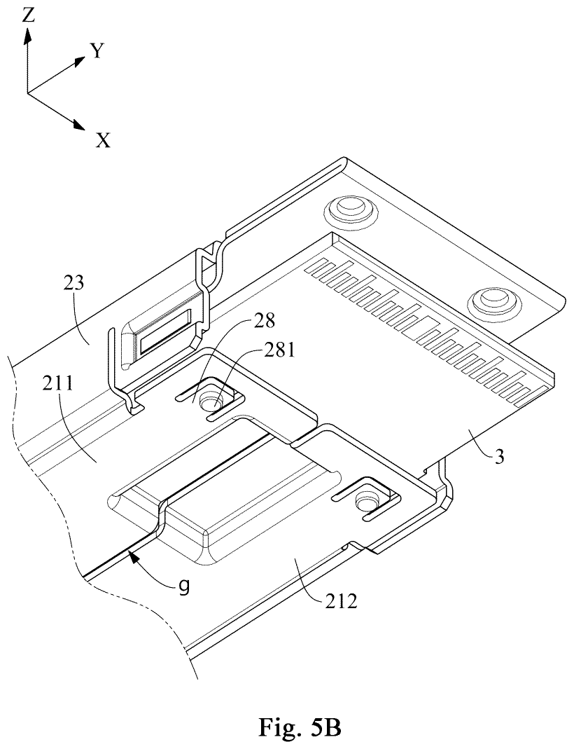

As shown in FIG. 2A, FIG. 2B, and FIG. 5A, a photoelectric conversion module 100 of an embodiment of the present invention includes at least a heat conduction structure 2 and a photoelectric conversion circuit board 3.

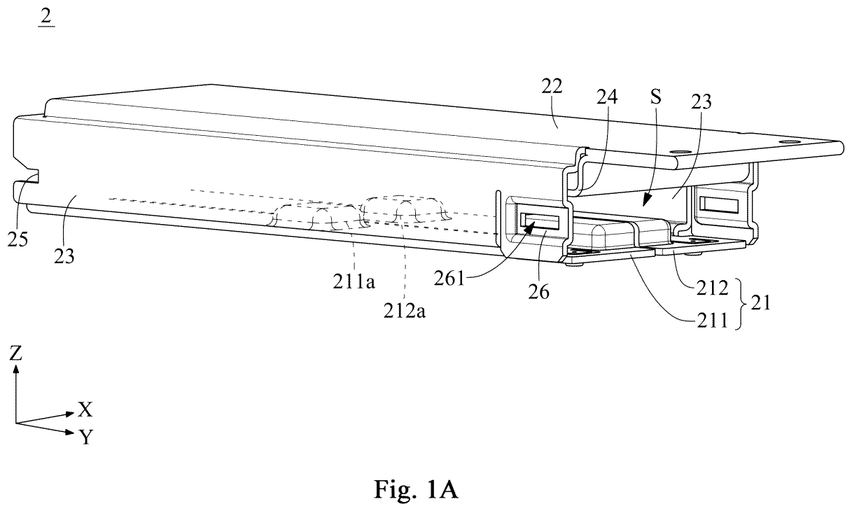

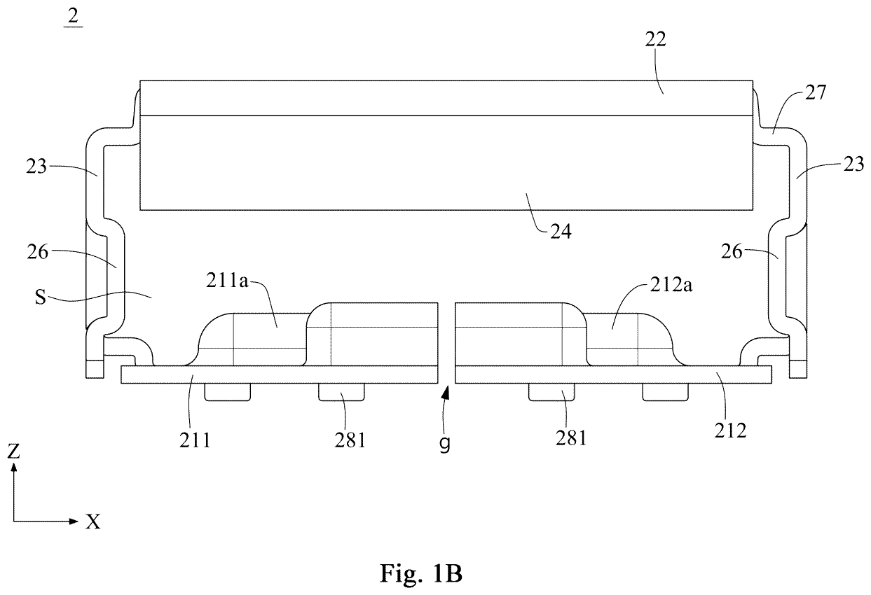

As shown in FIG. 1A and FIG. 1B, the heat conduction structure 2 includes a heat absorption wall 21, a heat conduction wall 22, and two side walls 23. The two side walls 23 are connected to the heat absorption wall 21 and the heat conduction wall 22. An accommodation space S is formed and surrounded by the heat absorption wall 21, the heat conduction wall 22, and the two side walls 23, and the accommodation space S is configured to accommodate the photoelectric conversion circuit board 3.

The heat absorption wall 21, the heat conduction wall 22, and the two side walls 23 are formed by bending a monolithic material. The heat absorption wall 21 is formed by two ends 211 and 212 of the monolithic material, and a gap g is existed between the two ends 211 and 212 of the monolithic material on a plane where the heat absorption wall 21 is located.

As shown in FIG. 2B, the heat conduction structure 2 formed by the monolithic material (including the heat absorption wall 21, the heat conduction wall 22, and the two side walls 23) can be in direct contact with a bottom of the photoelectric conversion circuit board 3, such that the heat energy generated by the photoelectric conversion circuit board 3 is transferred through an top surface of the board body and a through hole (not shown) of the board body to a bottom surface of the board body, then transferred through the heat absorption wall 21 and the side walls 23 on both sides to the heat conduction wall 22 above the photoelectric conversion circuit board 3, and finally dissipated through the heat conduction wall 22. In a heat conduction path of FIG. 2B, since the heat absorption wall 21, the heat conduction wall 22, and the two side walls 23 are an all-in-one-piece structure, the heat energy does not need to pass through a plurality of heat conduction elements (connections between the plurality of heat conduction elements will reduce the heat conduction rate), and the gap does not need to be filled with heat conduction glue. Therefore, the heat conduction rate is excellent, and the assembling efficiency and cost are also better than those of the prior art. In the present invention, the monolithic material means the same material (preferably a metal material with high heat conductivity) that forms a complete whole structure without external materials or structures processed in a way such as splicing, adhesion, and locking, and can be formed into a desired structure through stamping, cutting, bending, or the like.

In this embodiment, the heat conduction wall 22 can be externally connected to heat dissipation fins or other types of cooling devices to accelerate the dissipation of the heat energy. The aforementioned monolithic material is preferably a smooth sheet metal, so that the heat conduction wall 22 has a flat and smooth surface suitable for being connected to the heat dissipation fins or other types of cooling devices.

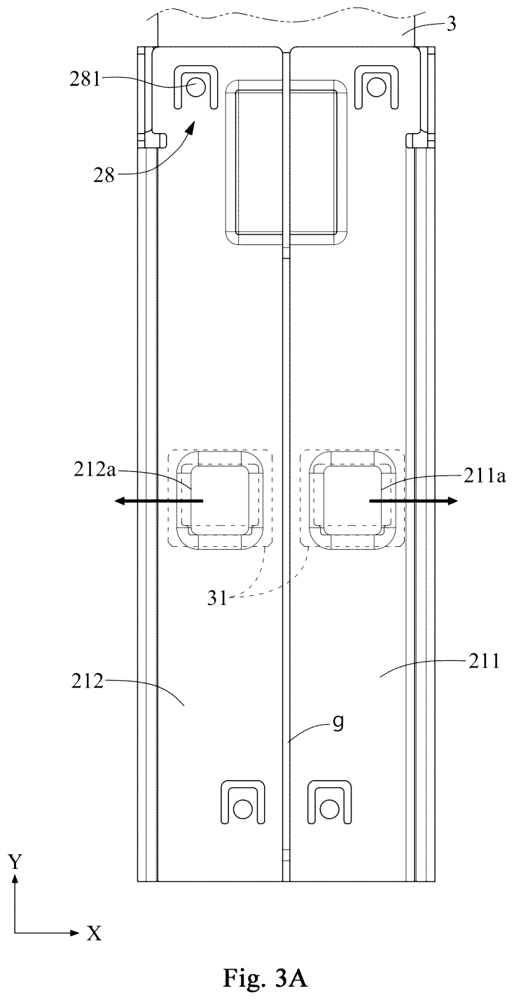

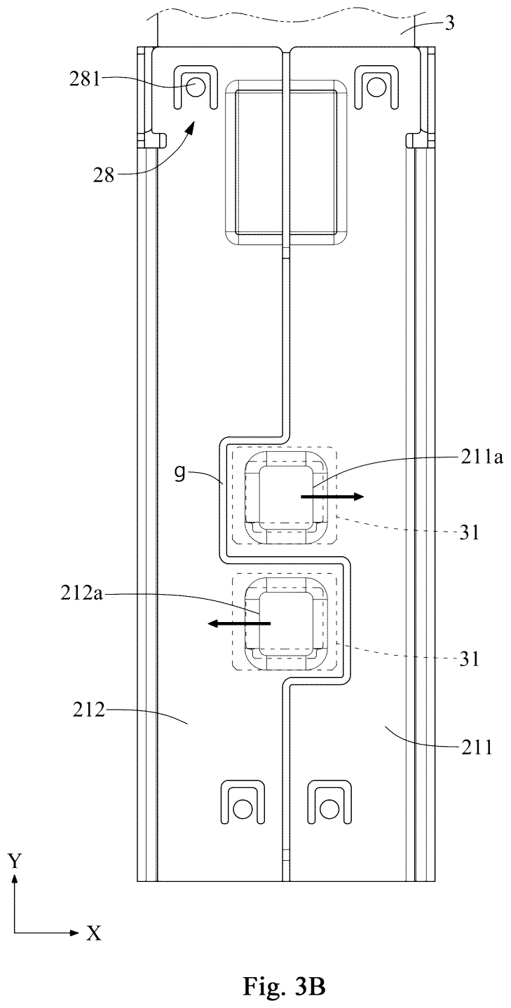

As shown in FIG. 2A and FIG. 2B, the photoelectric conversion circuit board 3 is arranged in the accommodation space S. The photoelectric conversion circuit board 3 is provided with a plurality of heat generating elements 31. The heat generating elements 31 may include elements specifically designed for photoelectric conversion (such as vertical cavity surface emitting lasers or photodiodes), or other electronic elements such as capacitors or resistors. The present invention does not limit the type of the heat generating element 31, and any element that may generate heat energy due to operation, whether active or passive, can be the heat generating element 31 in the present application. As shown in FIG. 2B and FIG. 3A, at least two of the plurality of heat generating elements 31 are located on two sides of the gap g respectively. Namely, there is no direct connection and contact between the two ends 211 and 212 of the monolithic material, thereby forming the gap g. At least two heat generating elements 31 correspond to the two ends 211 and 212 of the monolithic material and thus conduct heat through the two ends 211 and 212 of the monolithic material respectively. In this way, even if the photoelectric conversion circuit board 3 is densely provided with a plurality of heat generating elements 31 (a plurality of heating sources), the heat conduction structure 2 is to be provided with two ends 211 and 212 of the monolithic material far away from each other being in thermal contact with the heat generating elements 31 respectively, so that the heat sources are not accumulated in a specific area of the monolithic material, and the heat may be quickly dissipated away from the two sides, thereby avoiding overheating of the photoelectric conversion circuit board 3 and maintaining good operation thereof. The heat absorption wall 21 formed by the two ends 211 and 212 of the monolithic material may further have contact protrusions 211a and 212a (refer to FIG. 1B) toward the accommodation space S. The contact protrusions 211a and 212a are formed by stamping the monolithic material, and matched with the positions of the heat generating elements 31, such that the heat generating elements 31 are further tightly sealed, which improves the thermal conductivity.

FIG. 3B shows a heat conduction structure 2 in another form. When the heat generating elements 31 are not arranged horizontally (along the X-axis in the figure), the two heat generating elements 31 arranged in a straight line (along the Y-axis in the figure) can alternatively be located on two sides of the gap g through the non-linear gap g, so that the two ends 211 and 212 of the monolithic material are in thermal contact with the two heat generating elements 31, respectively. Furthermore, the gap g form of the heat conduction structure 2 of the present invention is not limited to this.

In summary, the photoelectric conversion module 100 of the present invention uses, by means of the heat conduction structure 2 formed by the monolithic material, a monolithic structure that is not connected with other heterogeneous material, to directly transfer heat energy from the bottom of the photoelectric conversion circuit board 3 through its sides to the top, without the need of heat conduction through numerous different stacked and complex heat conduction elements. In addition, when a plurality of heat generating elements generate heat simultaneously in adjacent areas, the heat conduction structure 2 of the present invention is to be provided with two ends 211 and 212 of the monolithic material far away from each other being in thermal contact with the heat generating elements 31, so that the heat sources are not be accumulated in a specific area of the monolithic material, and the heat may be quickly dissipated away from two sides, thereby avoiding overheating of the photoelectric conversion circuit board 3 and maintaining good operation thereof.

Further, as shown in FIG. 1B, the heat conduction structure 2 further includes an extension portion 24 parallel to the heat conduction wall 22, and the extension portion 24 is formed by bending the aforementioned monolithic material. The extension portion 24 can be used to be in thermal contact with top surfaces of the heat generating elements 31 of the photoelectric conversion circuit board 3 (the heat absorption wall 21 is in thermal contact with the bottom surface of the photoelectric conversion circuit board 3), so as to add a heat conduction path and increase the heat conduction speed. Furthermore, the extension portion 24 is a sheet material from the same whole structure with the heat conduction wall 22, thereby achieving better heat conductivity. Among the various heat generating elements 31, due to their different structures and heights, for some heat generating elements 31, their tops can be connected to the extension portion 24, and their bottoms can be heat dissipated by the heat absorption wall 21, thereby dissipating heat from both sides and increasing the heat dissipating speed. If some heat generating elements 31 cannot be in direct contact with the extension portion 24, the heat can still be conducted from the bottoms, namely, the heat is conducted by the heat absorption wall 21.

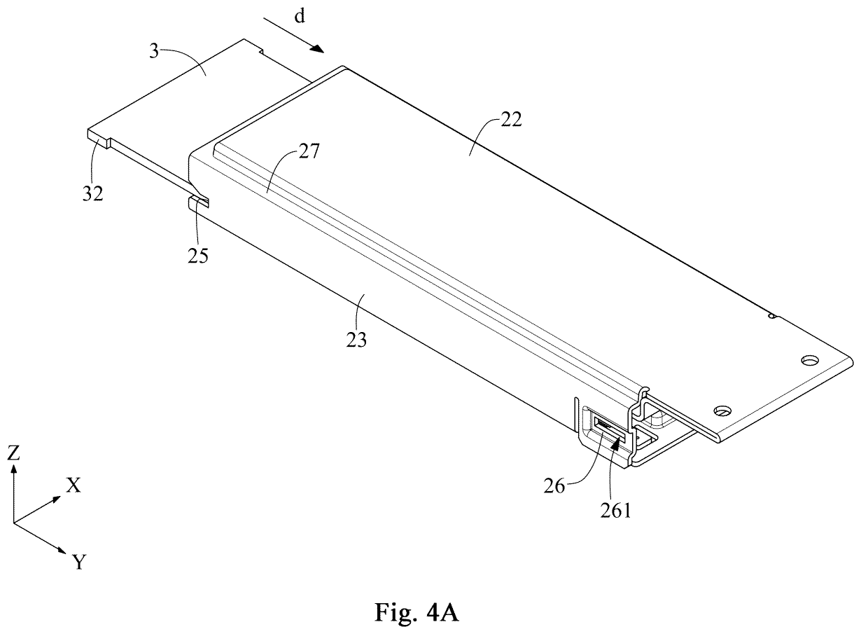

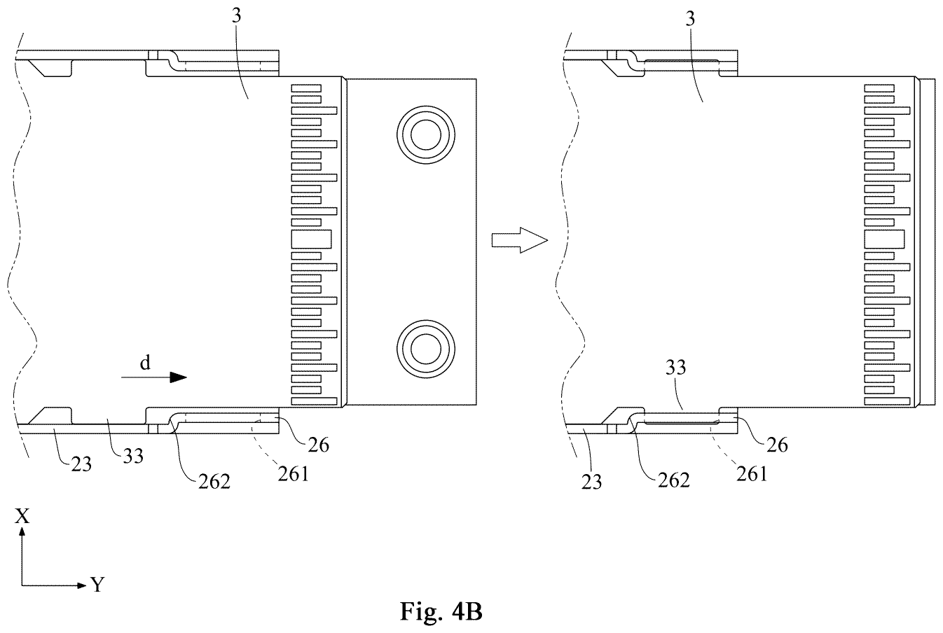

Further, as shown in FIG. 4A, the heat conduction structure 2 is provided with a first limiting feature 25 at a first end in an assembling direction d (parallel to the Y-axis in the figure) to restrict excessive movement of the photoelectric conversion circuit board 3 during assembling. In this embodiment, the first limiting feature 25 is a groove parallel to the assembling direction d, and a tail end of the photoelectric conversion circuit board 3 has a corresponding flange 32 to be limited by the first limiting feature 25. However, the present invention is not limited to this. In other embodiments, the first limiting feature 25 may also be in other forms.

Further, the heat conduction structure 2 is provided with a second limiting feature 26 at a second end in the assembling direction d. Referring to FIG. 4B, the second limiting feature 26 protrudes from the side wall 23 toward the accommodation space S. The second limiting feature 26 has a snap-fit recessed hole 261, and the photoelectric conversion circuit board 3 has a snap-fit bump 33 at a position corresponding to the snap-fit recessed hole 261. The snap-fit bump 33 is preferably a relatively protruding area formed by cutting off a portion of an edge of the photoelectric conversion circuit board 3. Since the second limiting feature 26 protrudes toward the accommodation space S, when the photoelectric conversion circuit board 3 moves in the assembling direction and passes through the second limiting feature 26, the snap-fit bump 33 is pressed and slightly elastically deformed, and then releases elastic potential energy such that it is clamped in the snap-fit recessed hole 261, so that the photoelectric conversion circuit board 3 is positioned in the heat conduction structure 2.

Preferably, the second limiting feature 26 has a guide slope 262 in the assembling direction d, and the guide slope 262 is inclined with respect to the assembling direction d. The guide slope 262 can guide the snap-fit bump 33 to gradually elastically deform through the slope.

Further, as shown in FIG. 2A, FIG. 2B, and FIG. 5A, the photoelectric conversion module 100 further includes a housing 1, and the heat conduction structure 2 is configured to be slidably arranged in the housing 1. The housing 1 can be used to assemble and accommodate other elements to form an integration with other devices, or can be used to protect the airtightness of the photoelectric conversion module 100. The housing 1 can completely surround the heat absorption wall 21, the heat conduction wall 22, and the two side walls 23 of the heat conduction structure 2, only leaving connection ports at the two ends. Alternatively, as shown in FIG. 2A and FIG. 5A, the heat conduction wall 22 can be exposed to dissipate heat or connect various heat dissipation devices.

Further, the housing 1 has a third limiting feature 13, and the third limiting feature 13 protrudes toward the heat conduction structure 2 in two directions (the Y-axis and the Z-axis in the figure) perpendicular to the assembling direction d to restrict movement of the heat conduction structure 2 beyond the assembling direction d. Accordingly, the heat conduction structure 2 is formed with a sliding rail 27 at a position adjacent to the third limiting feature 13, and the shape of the sliding rail 27 is matched with the third limiting feature 13. The heat conduction structure 2 is assembled by moving relative to the housing 1 with the aid of the sliding rail 27.

Further, as shown in FIG. 5A and FIG. 5B, the heat conduction structure 2 further includes at least one elastic sheet 28 arranged on the heat absorption wall 21. The elastic sheet 28 is provided with a positioning protrusion 281 toward the housing 1. A bottom surface 11 of the housing 1 has at least one positioning recess 12, and the position of the positioning recess 12 corresponds to the positioning protrusion 281. The elastic sheet 28 is preferably formed by cutting the aforementioned monolithic material, but the present invention is not limited to this. When the heat conduction structure 2 moves relatively in the assembling direction d, the clastic sheet 28 can be compressed due to its elasticity, which does not affect the movement of the heat conduction structure 2. When the heat conduction structure 2 is assembled to its position, the positioning protrusion 281 is clamped into the positioning recess 12 at the bottom surface 11 of the housing 1 to fix the heat conduction structure 2. The specific shape and number of the positioning protrusion 281 can be changed as needed, and it is better to avoid the positions where the contact protrusions 211a and 212a are formed. In other embodiments, the elastic sheet 28 may be alternatively arranged on the two side walls 23, but the present invention is not limited to this.

The present invention has been disclosed in the preceding text through the embodiments, but those skilled in the art should understand that these embodiments are only used to illustrate the present invention and should not be interpreted as limiting the scope of the present invention. It should be noted that any equivalent changes and substitutions to these embodiments shall fall within the scope of the present invention. Therefore, the protection scope of the present invention shall be defined in accordance with the scope of the patent application.

### DESCRIPTION OF NUMERALS

100: photoelectric conversion module
1: housing
11: bottom surface
12: positioning recess
13: third limiting feature
2: heat conduction structure
21: heat absorption wall
211: two ends of monolithic material
211a: contact protrusion
212: two ends of monolithic material
212a: contact protrusion
22: heat conduction wall
23: side wall
24: extension portion
25: first limiting feature
26: second limiting feature
261: snap-fit recessed hole
262: guide slope
27: sliding rail
28: clastic sheet
281: positioning protrusion
3: photoelectric conversion circuit board
31: heat generating element
32: flange
33: snap-fit bump
d: assembling direction
g: gap
S: accommodation space

I/We claim:

1. A heat conduction structure, comprising:
a heat absorption wall;
a heat conduction wall; and
two side walls connected to the heat absorption wall and the heat conduction wall, wherein an accommodation space is formed and surrounded by the heat absorption wall, the heat conduction wall, and the two side walls, and
wherein the heat absorption wall, the heat conduction wall, and the two side walls are formed by bending a monolithic material, the heat absorption wall is formed by two ends of the monolithic material, and a gap is existed between the two ends of the monolithic material on a plane where the heat absorption wall is located.

2. The heat conduction structure according to claim 1, wherein the heat absorption wall has a contact protrusion toward the accommodation space, and the contact protrusion is formed by stamping the monolithic material.

3. The heat conduction structure according to claim 1, further comprising an extension portion parallel to the heat conduction wall, wherein the extension portion is formed by bending the monolithic material.

4. A photoelectric conversion module, comprising:
a heat conduction structure having a heat absorption wall, a heat conduction wall, and two side walls connected to the heat absorption wall and the heat conduction wall, wherein an accommodation space is formed and surrounded by the heat absorption wall, the heat conduction wall, and the two side walls; and
a photoelectric conversion circuit board arranged in the accommodation space, wherein the photoelectric conversion circuit board is provided with a plurality of heat generating elements,
wherein the heat absorption wall, the heat conduction wall, and the two side walls are formed by bending a monolithic material, the heat absorption wall is formed by two ends of the monolithic material, a gap is existed between the two ends of the monolithic material on a plane where the heat absorption wall is located, and at least two of the plurality of heat generating elements are located on two sides of the gap, respectively.

5. The photoelectric conversion module according to claim 4, wherein the heat conduction structure is provided with a first limiting feature at a first end in an assembling direction, and the first limiting feature is a groove parallel to the assembling direction.

6. The photoelectric conversion module according to claim 4, wherein the heat conduction structure is provided with a second limiting feature at a second end in an assembling direction, the second limiting feature protrudes from the side wall toward the accommodation space, the second limiting feature has a snap-fit recessed hole, and the photoelectric conversion circuit board has a snap-fit bump at a position corresponding to the snap-fit recessed hole.

7. The photoelectric conversion module according to claim 6, wherein the second limiting feature has a guide slope in the assembling direction, and the guide slope is inclined with respect to the assembling direction.

8. The photoelectric conversion module according to claim 4, further comprising a housing, wherein the heat conduction structure is configured to be slidably arranged in the housing.

9. The photoelectric conversion module according to claim 8, wherein the housing has a third limiting feature, and the third limiting feature protrudes toward the heat conduction structure in two directions perpendicular to an assembling direction to restrict movement of the heat conduction structure beyond the assembling direction.

10. The photoelectric conversion module according to claim 8, wherein the heat conduction structure further comprises at least one elastic sheet arranged on the heat absorption wall, the elastic sheet is provided with a positioning protrusion toward the housing, and a bottom surface of the housing has at least one positioning recess at a position corresponding to the positioning protrusion.
